(19) United States
(12) Patent Application Publication
(10) Pub. No.: US 2013/0263906 A1
(43) Pub. Date: Oct. 10, 2013

(54) THERMOELECTRIC CONVERSION ELEMENT AND THERMOELECTRIC CONVERSION MODULE

(71) Applicant: PANASONIC CORPORATION, Osaka (JP)

(72) Inventors: Satoshi Maeshima, Hyogo (JP); Kaori Toyoda, Hyogo (JP); Takaaki Higashida, Osaka (JP); Takashi Kubo, Osaka (JP)

(73) Assignee: PANASONIC CORPORATION, Osaka (JP)

(21) Appl. No.: 13/836,664

(22) Filed: Mar. 15, 2013

(30) Foreign Application Priority Data
Apr. 9, 2012 (JP) 2012-088346
Feb. 6, 2013 (JP) 2013-021386

(51) Int. Cl. H01L 35/32

(52) U.S. Cl. CPC H01L 35/32
USPC 136/205

(57) ABSTRACT

A thermoelectric conversion element and a thermoelectric conversion module in which a high density arrangement is easily performed and connection reliability is high, and a manufacturing method thereof are provided. A thermoelectric conversion element is provided which includes a tube, a thermoelectric conversion material which is filled in the tube, and a plated metal layer which is plated on one end or both ends of the thermoelectric conversion material, wherein the thermoelectric conversion material protrudes from an end surface of the tube, and the plated metal layer covers the protrusion of the thermoelectric conversion material. Moreover, a thermoelectric conversion module which is configured to connect the thermoelectric conversion elements in series is provided.

### CROSS REFERENCE TO RELATED APPLICATIONS

This application is entitled to the benefit: of Japanese Patent Application No. 2012-088346, filed Apr. 9, 2012, and Japanese Patent Application No. 2013-021386, filed Feb. 6, 2013, the entire contents of which are incorporated by reference herein,

### TECHNICAL FIELD

The present invention relates to a thermoelectric conversion element and a thermoelectric conversion module.

### BACKGROUND ART

A thermoelectric conversion element has been developed as a power generating element which uses Seebeck effect. For example, a power generation system which uses industrial exhaust heat is studied. However, improvements such as low thermoelectric conversion efficiency and high power-generation costs are required.

An example of a thermoelectric conversion module which includes the thermoelectric conversion elements is shown in FIG. 1 (refer to PTL 1). In thermoelectric conversion module 100 shown in FIG. 1, P-type thermoelectric conversion elements and N-type thermoelectric conversion elements 60 are connected to each other in series through connection electrodes 70, and thus, a plurality of PN element pairs are formed. Ceramic substrate 80 is disposed on one end surface of the PN element pairs, and ceramic substrate 90 is disposed on the other end surface of the PN element pairs. Ceramic substrate 80 is heated, other ceramic substrate 90 of the element pairs is cooled (is not heated), and thus, electricity is generated. The arrows in FIG. 1 show a flow of heat due to heating and cooling. The generated electricity is extracted through a pair of current introduction terminals 15 and 15′.

In the thermoelectric conversion module shown in FIG. 1, P-type thermoelectric conversion elements 50 and N-type thermoelectric conversion elements 60 are arranged so as not to contact each other, and it is necessary to prevent short circuits between elements. In order to securely prevent the short circuits, sufficient element intervals are required, and the element intervals raise the decrease in output density per a unit area of the thermoelectric conversion module.

With respect to this, various manufacturing methods of the thermoelectric conversion module are suggested (refer to PTLs 2 and 3). FIG. 2 shows an outline of a method which is suggested in PTL 2. As shown in FIG. 2, P-type thermoelectric conversion materials 150 and N-type thermoelectric conversion materials 160 are inserted into the inner portion of honeycomb molding die 110, and insulating resin 120 is impregnated and hardened, and block 130 in which the entire configuration is integrated is molded. Subsequently, block 130 is cut in each predetermined thickness by cutter 140 in a direction orthogonal to the longitudinal direction of each element, so as to obtain block pieces 130′. In block piece 130′, P-type thermoelectric conversion elements 151 and N-type thermoelectric conversion elements 161 are alternately disposed. P-type thermoelectric conversion elements 151 and N-type thermoelectric conversion elements 161 are plated so as to he connected in series to each other, and thus, a thermoelectric conversion module is obtained.

In the thermoelectric conversion module obtained in this way, since P-type thermoelectric conversion materials 150 and N-type thermoelectric conversion materials 160 are covered with an insulating resin, short circuits between thermoelectric conversion elements are securely prevented. Accordingly, the thermoelectric conversion module can be obtained in which P-type thermoelectric conversion elements 151 and N-type thermoelectric conversion elements 161 are densely arranged.

Moreover, a metal film such as a plated metal is provided on both end surfaces of thermoelectric conversion materials in various thermoelectric conversion elements (for example, refer to PTLs 4 to 9).

### CITATION LIST

### Patent Literature

PTL 1: Japanese Patent No. 3958857
PTL 2: Japanese Patent Application Laid-Open No. 2009-76603
PTL 3: United States Patent Application Laid-Open No. 2007/0221264
PTL 4: Japanese Patent Application Laid-Open No. 2002-359405
PTL 5: Japanese Patent Application Laid-Open No. 2009-43783
PTL 6: Japanese Patent Application Laid-Open No. 2001-237465
PTL 7: Specification of U.S. Pat. No. 6,297,441
PTL 8: United States Patent Application Laid-Open No. 2003/0019216
PTL 9: Specification of U.S. Pat. No. 6,232,542

### SUMMARY OF INVENTION

### Technical Problem

The thermoelectric conversion module is a device in which one end (refer to ceramic substrate 80 in FIG. 1) is exposed to a high temperature, the other end (refer to ceramic substrate 90 in FIG. 1) is exposed to a low temperature, and thus, electricity is generated. Since the thermoelectric conversion module is used for a long time in a state where a temperature difference exists, thermal stress easily occurs in a portion joined between the thermoelectric conversion element and a wiring portion (refer to connection electrode 70 in FIG. 1) by a difference of thermal expansion due to the temperature difference. When the thermal stress is increased in the portion joined between the thermoelectric conversion element and the wiring portion, there is a concern that cracks may occur in the joined portion or the like, and joining reliability is decreased. As a result, the reliability of the thermoelectric conversion module itself is decreased.

The present invention is to solve the above-described problems of the related art, and an object thereof is to provide a thermoelectric conversion element and a thermoelectric conversion module in which a high density arrangement is easily performed and connection reliability is high, and a manufacturing method thereof.

### Solution to Problem

The present invention relates to a thermoelectric conversion element and a thermoelectric conversion module described below.
[1] According to an aspect of the present invention, there is provided a thermoelectric conversion element including: an insulating tube; a thermoelectric conversion material with which the tube is filled; and a plated metal layer which is plated on one end or both ends of the thermoelectric conversion material, wherein the thermoelectric conversion material protrudes from an end surface of the tube, and the plated metal layer covers the protrusion of the thermoelectric conversion material.
[2] in thermoelectric conversion element of the aspect, a height of the thermoelectric conversion material which protrudes from the end surface of the tube may be within 5% of a height of the thermoelectric conversion element.
[3] In thermoelectric conversion element of the aspect, the tube may be a glass tube.
[4] in thermoelectric conversion element of the aspect, both ends of the thermoelectric conversion material may protrude from end surfaces of the tube, and the plated metal layer may cover the protrusions of both ends of the thermoelectric conversion material.
[5] In thermoelectric conversion element of the aspect, the plated metal layer covers a top surface and a side surface of the protrusion of the thermoelectric conversion material.
[6] According to another aspect of the present invention, there is provided a thermoelectric conversion module including: a P-type thermoelectric conversion element which includes an insulating tube, a P-type thermoelectric conversion material with which the tube is filled, and a plated metal layer which is plated on one end or both ends of the P-type thermoelectric conversion material; an N-type thermoelectric conversion element which includes an insulating tube, an N-type thermoelectric conversion material with which the tube is filled, and a plated metal layer which is plated on one end or both ends of the N-type thermoelectric conversion material; and
an electric circuit board which is soldered to the P-type thermoelectric conversion element and the N-type thermoelectric conversion element through the plated metal layer, and is that electrically connects the P-type thermoelectric conversion element with the N-type thermoelectric conversion element in series,
   wherein the P-type thermoelectric conversion material and the N-type thermoelectric conversion material protrude from the end surface of the tube respectively, and the plated metal layer covers the protrusion of the thermoelectric conversion material.

### Advantageous Effects of invention

In the thermoelectric conversion element of the present invention, since the thermoelectric conversion material is filled in the insulating tube, a short circuit between thermoelectric conversion elements is securely prevented. Thereby, the thermoelectric conversion elements can be arranged to closely contact each other, and the thermoelectric conversion module in which the thermoelectric conversion elements arc densely arranged is obtained. Moreover, in the thermoelectric conversion element of the present invention, an end part of the thermoelectric conversion material with which the tube is filled protrudes from the end surface of the tube, and the protrusion is covered by the plated metal layer. Thereby, when the thermoelectric conversion element is soldered to the electric circuit board through the plated metal layer, the joining strength between the thermoelectric conversion element and the electric circuit hoard is increased, and the mounting reliability is increased.

### BRIEF DESCRIPTION OF DRAWINGS

FIG. 1 is a view showing an example of a thermoelectric conversion module of the related art;

FIG. 2 is a view showing an example of a manufacturing flow of the thermoelectric conversion module of the related art;

FIGS. 3A and 3B are a perspective view and a cross-sectional view of a thermoelectric conversion element of the present invention respectively;

FIG. 4 is a cross-sectional view of the thermoelectric conversion module of the present invention;

FIGS. 5A and 5B arc views showing Example 1 and Example 2 with respect to a joint of the thermoelectric conversion element which is soldered to an electric circuit board in the thermoelectric conversion module of the present invention respectively;

FIGS, 6A and 6B are views showing Example 1 and Example 2 with respect to a joint of a thermoelectric conversion element which is soldered to an electric circuit board in a thermoelectric conversion module of a comparative example respectively; and

FIG. 7 is a view showing a shape of a blade of a cutter which is used so as to cause the thermoelectric conversion material to protrude from an end surface of a tube.

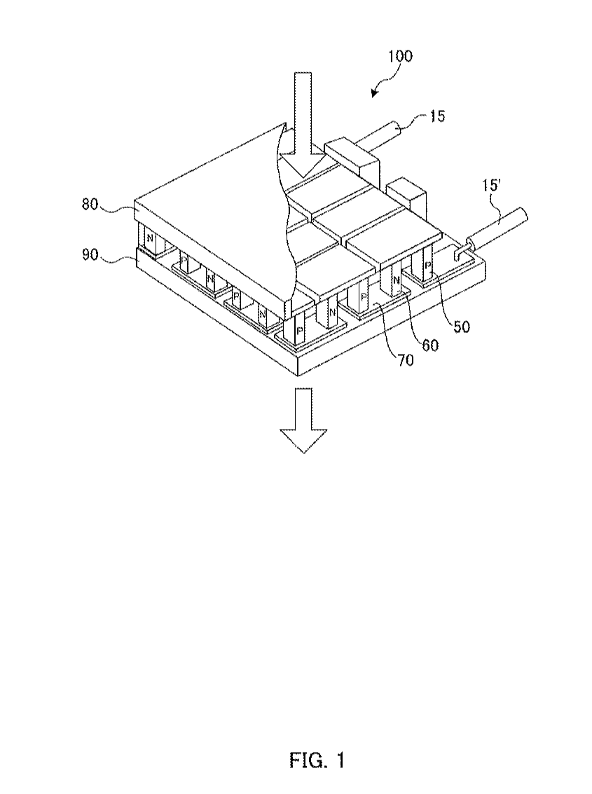

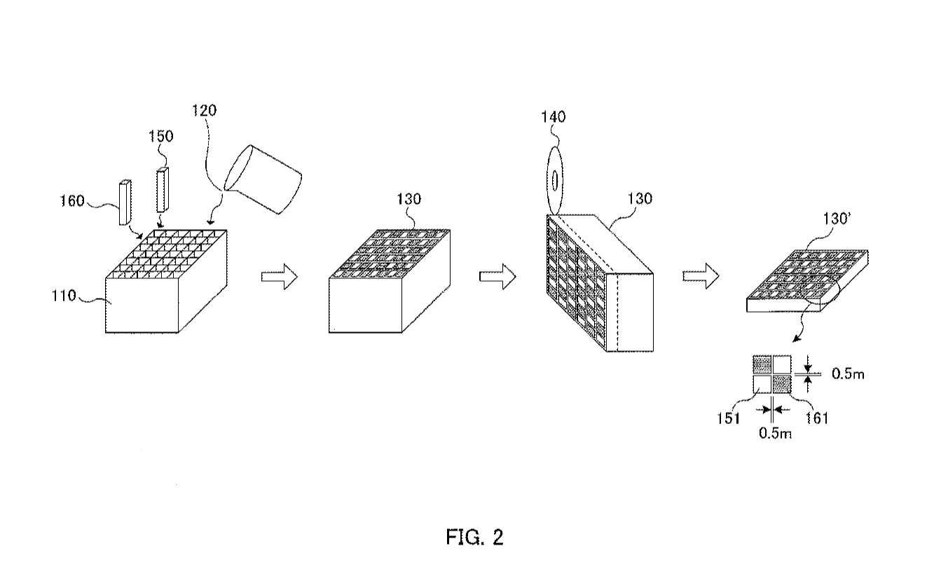

### DESCRIPTION OF EMBODIMENTS

1. Thermoelectric Conversion Element

A thermoelectric conversion element of the present invention includes an insulating lube, a thermoelectric conversion material with which the tube is filled, and a plated metal layer which is plated to one end or both ends of the thermoelectric conversion material.

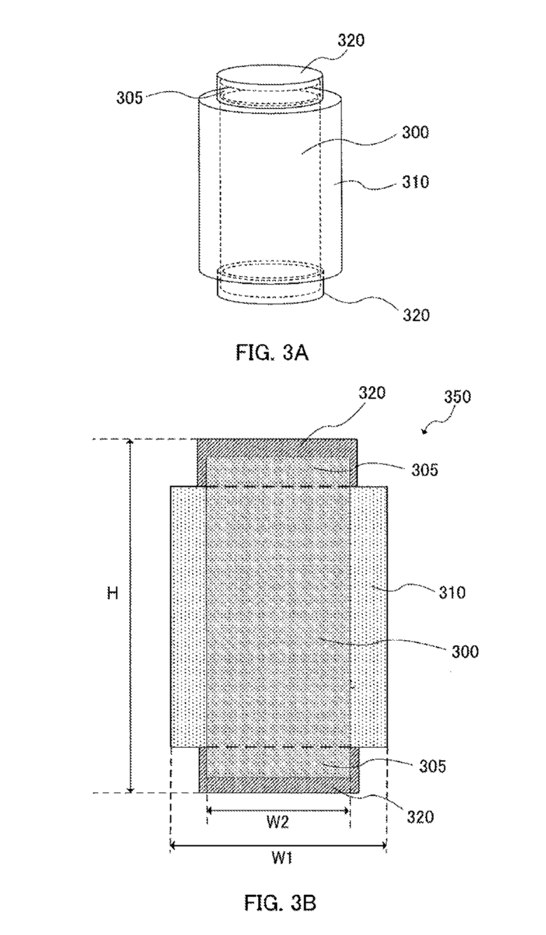

FIG, 3A is a perspective view of the thermoelectric conversion element and FIG. 3B is a cross-sectional view of the thermoelectric conversion clement. As shown in FIGS. 3A and 3B, the thermoelectric conversion material which is filled in the tube of the thermoelectric conversion element protrudes from one opening end or both opening ends of the tube (preferably, from both opening ends). FIGS. 3A and 3B show the state where the end parts of thermoelectric conversion material 300 protrudes from both ends of tube 310. Protrusion 305 of thermoelectric conversion material 300 is covered with plated metal layer 320. Height H of thermoelectric conversion element 350 is preferably 1.0 to 3.0 mm, and is more preferably 1.0 to 2.0 mm. Diameter W1 of thermoelectric conversion element 350 is preferably 0.6 to 0.1 mm. Moreover, diameter W2 of thermoelectric conversion material 300 is preferably 0.5 to 2.0

In the thermoelectric conversion element, it is preferable that the tube be formed of a heat-resistant insulating material. For example, the heat-resistant insulating material includes glass, quartz, ceramic, a heat-resistant organic resin, or the like, and preferably includes heat-resistant glass (a material which is a kind of borosilicate glass in which SiO₂ and B₂O₃ are mixed and has coefficient of thermal expansion of approximately 3×10⁻⁶/K). In the thermoelectric conversion element, the both ends of the tube are opened. In the thermoelectric conversion element, the inner diameter and the outer diameter of the tube are not particularly limited respectively, and may be 1.8 mm and 3 mm.

In the thermoelectric conversion element, the thermoelectric conversion material with which the tube is filled is a material which generates an electromotive force when a temperature difference is applied. The thermoelectric conversion material may be selected according to the temperature difference which is generated at the time of use. For example, the thermoelectric conversion material is preferably a bismuth-tellurium based material (Bi—Te based material) when the temperature difference is within a range from a normal temperature to 500 K, a lead-tellurium based material (Pb—Te based material) when the temperature difference is within a range from a normal temperature to 800 K, and a silicon-germanium based material (Si—Ge based material) when the temperature difference is within a range from a normal temperature to 1,000 K. As the thermoelectric conversion material which has improved power generation performance around a normal temperature, there is a Bi—Te based material.

It is preferable that the thermoelectric conversion material with which the tube is filled in the thermoelectric conversion element be doped into P-type or N-type. The thermoelectric conversion element in which the thermoelectric conversion material is doped into P-type is referred to as a P-type thermoelectric conversion element, and the thermoelectric conversion element in which the thermoelectric conversion material is doped into N-type is referred to as an N-type thermoelectric conversion element.

The doping is performed by adding a dopant to the thermoelectric conversion material. For example, the p-type dopant includes Sb, and the n-type dopant includes Sc, By the addition of the dopants, the thermoelectric conversion material forms mixed crystals. Therefore, for example, the additional amount of the dopant into the thermoelectric conversion material is adjusted so as to satisfy the composition formula of the materials such as “Bi_{0.5}Sb_{1.5}Te₃” or “Bi₂Te_{2.l Se}_{0.3}.”

The thermoelectric conversion material in the thermoelectric conversion element includes protrusion 305 which protrudes from the end surface of the tube (refer to FIG. 3B). The thermoelectric conversion material with which the tube is filled may protrude so as to have protrusion 305 as shown in FIG. 3B, and protrusion 305 may also he processed in a desired shape. For example, described below, the surface of protrusion 305 may he roughened, and thus adhesiveness between the surface and plated metal layer 320 can be increased.

It is preferable that the plated metal layer in the thermoelectric conversion element cover a portion (protrusion) of the thermoelectric conversion material, the portion protruding from the end surface of the tube. Covering the protrusion means covering at least a portion of the protrusion. However, it is preferable that whole of the portion which protrudes from the end surface of the tube be covered. As shown in FIG. 3B, it is preferable that the top surface and the side surface of the protrusion be covered with the plated metal layer 320 such that plated metal layer 320 contacts the end surface of tube 310.

The plated metal layer is preferably a metal having high wettability with respect to solder and a metal which has a property (barrier property) required for preventing the solder components from diffusing to the thermoelectric conversion material. The type of the plated metal is not particularly limited. However, nickel plating, molybdenum plating, or the like is preferable.

As described below, since the protrusion is covered with the plated metal layer, joining strength between the thermoelectric conversion element and a circuit can be increased. Moreover, deterioration due to oxidation of the thermoelectric conversion material is prevented, or it is possible to prevent components which configure the solder for joining to the circuit from diffusing to the thermoelectric conversion element.

Manufacturing Method of Thermoelectric Conversion Element

A manufacturing method of the thermoelectric conversion element of the present invention is not particularly limited. However, for example, the thermoelectric conversion element may be manufactured according to the following flow which includes 1) a step where the tube is filed with the thermoelectric conversion material, 2) a step where the end part of the tube filled with the thermoelectric conversion material is removed, and 3) a step where the plated metal layer is formed on the protrusion of the thermoelectric conversion material which is exposed due to the removal of the end portion of the tube.

1) For example, in order to fill the thermoelectric conversion material in the tube, powder of the thermoelectric conversion material can be filled in the tube, the tube filled with the power f the thermoelectric conversion material is heated so as to melt and liquefy the powder the thermoelectric conversion material. The melting the powder of the thermoelectric conversion material may be performed by placing the tube into a heating furnace or by heating the tube through a heater. The tube can he successively heated from one end toward the other end, and thus, crystal orientation of the thermoelectric conversion material is easily arranged in one direction. And thereby, efficiency of generation of power of the thermoelectric conversion element is easily increased.

Moreover, 1) for example, in order to fill the tube with the thermoelectric conversion material, the end of the tube is immersed in the melted thermoelectric conversion material, anal the thermoelectric conversion material may be sucked up by decompressing the inner portion of the tube.

When the length of the tube filled with the thermoelectric conversion material is too long, the tube may be cut in a perpendicular direction with respect to the lung axis of the tube so as to be diced. Each diced material becomes the thermoelectric conversion element.

Subsequently, 2) the end part of the tube filled with the thermoelectric conversion material is removed, and thus, an end part of the thermoelectric conversion element protrudes from the end surface of the tube. As described above, the material of the tube of the thermoelectric conversion element is glass or an organic resin. When the tube is glass, the end part of the tube is dissolved by hydrogen fluoride so as to remove only the end part of the tube, and not to dissolve the thermoelectric conversion material. When the tube is an organic resin, the end part of the tube is dissolved by organic solvent or the like which dissolves the resin so as to remove only the end part of the tube, and not to dissolve the thermoelectric conversion material.

While removing the end part of the tube, if there is a concern that the thermoelectric conversion material or the inner portion of the tube may be damaged, it is preferable that the end part of the tube be removed in a state where the thermoelectric conversion material is masked. For example, when the tube is dissolved by hydrogen fluoride, it is preferable that the thermoelectric conversion material be masked by paraffin, polyethylene, Teflon (registered trademark), or the like.

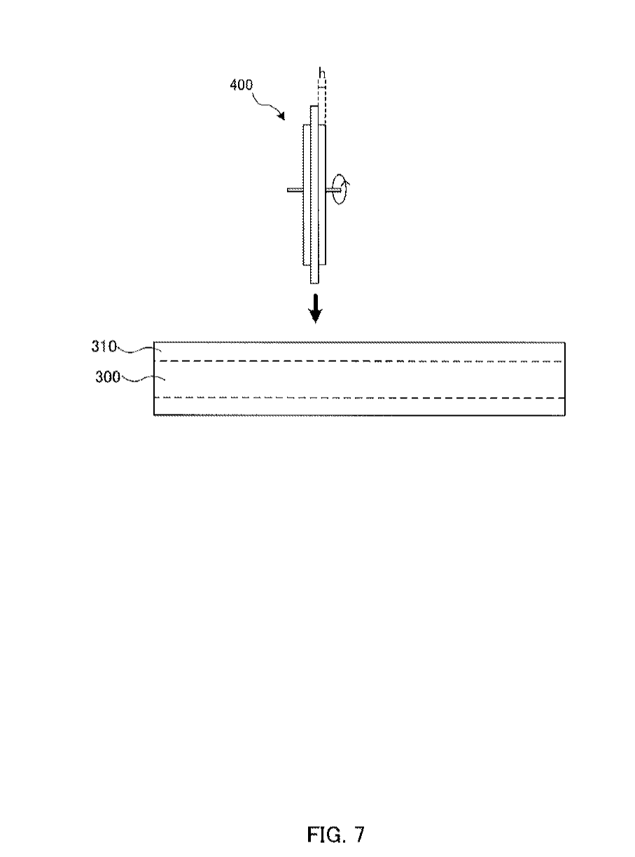

Naturally, means for removing the end part of the tube is not limited to the above-described. For example, tube 310 filled with thermoelectric conversion material 300 is out using cutter 401) shown in FIG. 7, and thus, an element in which an end part of the thermoelectric conversion material protrudes from the end surface of the tube can be obtained. Cutter 400 shown in FIG. 7 includes a cutter blade having steps. When the cutter is pressed while rotating against the tube filled with thermoelectric conversion material 300, and cuts the tube filled with the thermoelectric conversion material. And thereby, the element in which an end part of thermoelectric conversion material 300 protrudes from the end surface of tube 310 can be obtained. The protruding height can be adjusted by the height h of the step of the cutting blade of cutter 400. When the above-described dicing process is performed using cutter 400, the end of the tube can also be removed in the dicing process.

Moreover, 3) the plated metal layer is formed on the protrusion of the thermoelectric conversion material which is exposed by the removal of the end of the tube. The method of forming the plated metal layer is not particularly limited.

2. Thermoelectric Conversion Module

The thermoelectric conversion module includes P-type thermoelectric conversion elements and N-type thermoelectric conversion elements. Moreover, the P-type thermoelectric conversion elements and N-type thermoelectric conversion elements are electrically connected to each other in series. For example, the electric connections between the P-type thermoelectric conversion elements and the N-type thermoelectric conversion elements are performed by mounting each thermoelectric conversion element on an electric circuit hoard on which electric circuit are printed. For example, the electric circuit board includes a ceramic substrate (for example, aluminum oxide) having high thermal conductivity and a printed circuits formed of copper on the substrate. The thermoelectric conversion elements are connected to the circuits of the electric circuit board through the plated metal layers, so as to mount the thermoelectric conversion elements on the electric circuit board.

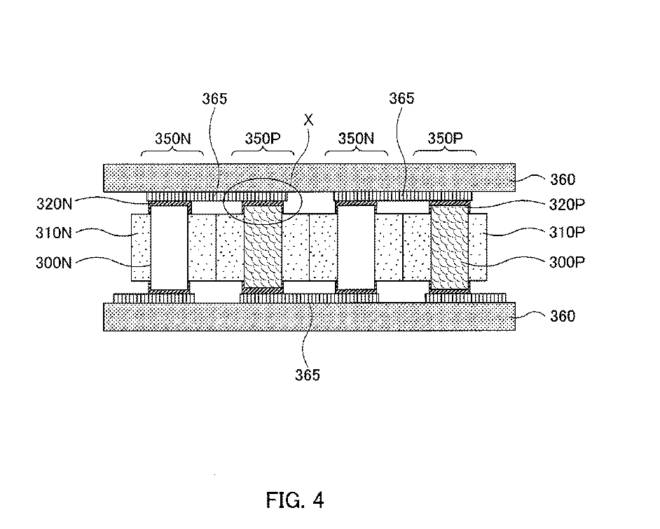

FIG. 4 shows a cross-sectional view when the thermoelectric conversion elements of the thermoelectric conversion module are cut in the long axis direction of the thermoelectric conversion element. The thermoelectric conversion module shown in FIG. 4 includes P-type thermoelectric conversion elements 350P and N-type thermoelectric conversion elements 350N. P-type thermoelectric conversion element 350P includes tube (for example, glass tube) 310P, P-type thermoelectric conversion material 300P which is filled in the tube, and plated metal layers 320P which are formed on both ends of P-type thermoelectric conversion material 300P. Similarly, N-type thermoelectric conversion element 350N includes tube (for example, glass tube) 310N N-type thermoelectric conversion material 300N which is filled in the tube, and plated metal layers 320N which are formed on both ends of N-type thermoelectric conversion material 300N.

As shown in FIG. 4, P-type thermoelectric conversion clement 350P and N-type thermoelectric conversion element 350 N are arranged so as to closely contact each other. Specifically, tube 310P and tube 310N are arranged so as to contact each other in thermoelectric conversion elements 350 of the present invention, since thermoelectric conversion material 300 is covered with insulating tube 310, even when the conversion elements are arranged so as to closely contact each other, there is no concern that a short circuit may occur. Thereby, the thermoelectric conversion elements can be arranged so as to closely contact each other and can be densely disposed.

P-type thermoelectric conversion element 350P and N-type thermoelectric conversion element 350N are mounted on electric circuit hoard 360. Specifically, P-type thermoelectric conversion element 350P and N-type thermoelectric conversion element 350N are soldered to circuit 365 of electric circuit board 360 through plated metal layers (320P and 320N) which are formed on both ends of thermoelectric conversion materials (300P and 300N). Moreover, circuit 365 of electric circuit hoard 360 electrically connects in series P-type thermoelectric conversion element 350P with N-type thermoelectric conversion element 350N.

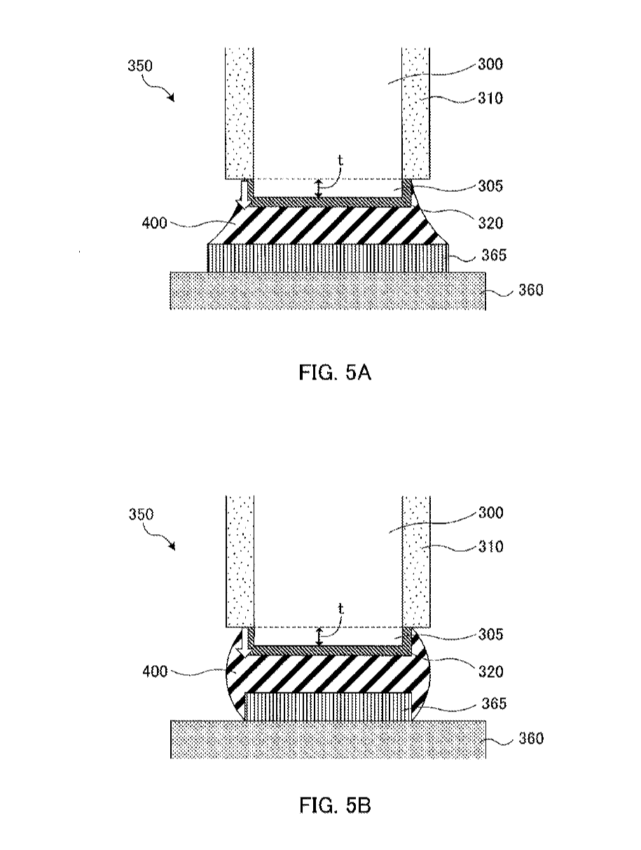

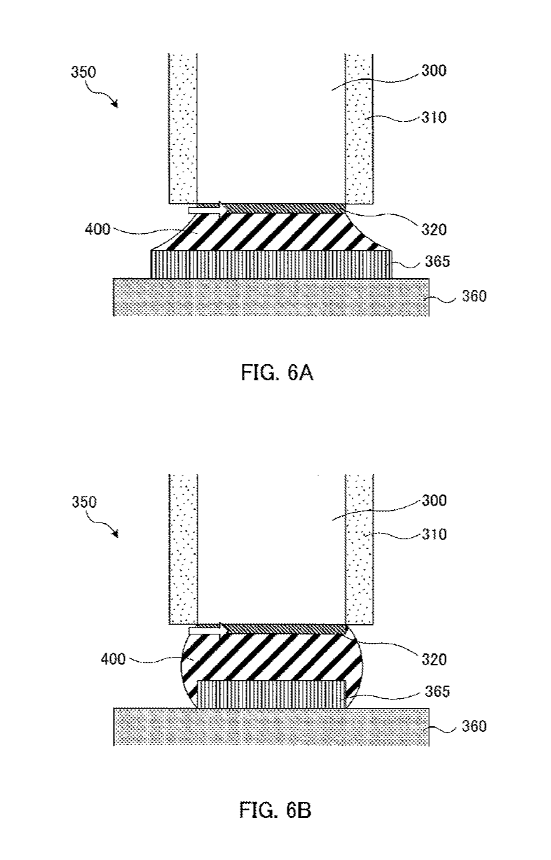

An example of the state of the joint (corresponding to X portion in FIG. 4) is shown in FIGS. 5A and 5B, the joint being between thermoelectric conversion element 350 of the present invention and electric circuit board 360 on which thermoelectric conversion element 350 is mounted. FIG. 5A shows a case where the width of circuit 365 of electric circuit board 360 is larger than the width of thermoelectric conversion material 300 of thermoelectric conversion element 350, and FIG. 5B shows a case where the width of thermoelectric conversion material 300 of thermoelectric conversion element 350 and the width of circuit 365 of electric circuit board 360 are the same as each other. As shown in FIGS. 5A and 5B, solder 400 tightly adheres to plated metal layer 320 which covers protrusion 305.

On the other hand, FIGS. 6A and 6B show a case where the thermoelectric conversion element, in which the end part of the thermoelectric conversion material does not protrude from the tube, is mounted on the electric circuit board. FIG. 6A shows a case where the width of circuit 365 of electric circuit board 360 is larger than the width of thermoelectric conversion material 300 of thermoelectric conversion element 350, and FIG. 6B shows a ease where the width of thermoelectric conversion material 300 of thermoelectric conversion element 350 and the width of circuit 365 of electric circuit board 360 are the same as each other. As shown in FIGS. 6A and 613, solder 400 is joined to plated metal layer 320 which covers only the top surface of the thermoelectric conversion material 300.

In the joined state shown in FIG. 6A and 6B, cracks easily progress in the arrow direction (short axis direction of the element) shown in FIG. 6. Thereby, a separation between thermoelectric conversion element 350 and electric circuit hoard 360 easily occurs, and the connection reliability may be not sufficient. On the other hand, in the joined state shown in FIGS. 5A and 5B, cracks do not easily progress in the short axis direction of the element, rather, cracks may progress in the arrow direction (long axis direction of the element) shown in FIGS. 5A and 5B. The reason is because plated metal layer 320 is formed on protrusion 305, and solder 400 tightly adheres to the side surface as well as the top surface of protrusion 305,

Generally, as shown in FIGS. 6A and 6B, separation between the element mounted on the circuit of the electric circuit board and the circuit occurs due to the fact that cracks occur in the facing surface of the element to the circuit. Thereby, as shown in FIGS. 5A and 5B, since cracks do not easily occur in the facing surface, the joining strength between the thermoelectric conversion element and the circuit can be increased.

The larger protruding height t (refer to FIGS. 5A and 5B) from the end surface of the tube of the thermoelectric conversion material, the easier the increase of the joining strength between the thermoelectric conversion element and the circuit. On the other hand, if the protruding height t is too increased, a thermoelectric conversion function of the thermoelectric conversion element is decreased. Thereby, it is preferable that the protruding height t be within 5% with respect to the height (the length in the long axis direction) of the element. For example, it is preferable that the protruding height t be 10 to 100 μm when the height of the element is 2 mm.

Particularly, as shown in FIG. 5A., when the shape of the solder is a fillet shape, the joining strength between thermoelectric conversion element 350 and circuit 365 can be increased. The fillet shape can mean “a tapered shape with spreading toward bottom.” On the other hand, as shown in FIG. 5B, when the width of circuit 365 of electric circuit board 360 is the same as or is smaller than the width of thermoelectric conversion material 300 of thermoelectric conversion element 350, there is an advantage that the mounting density of thermoelectric conversion elements 350 can be increased.

### INDUSTRIAL APPLICABILITY

In the thermoelectric conversion module of the present invention, the connection reliability between the thermoelectric conversion element and the electric circuit board for electrically connecting the thermoelectric conversion elements is high. Thereby, in the thermoelectric conversion module of the present invention, long-term reliability is high.

### REFERENCE SIGNS LIST

15 and 15′: current introduction terminal.
50: P-type thermoelectric conversion element
60: N-type thermoelectric conversion element
70: connection electrode
80: ceramic substrate
90: ceramic substrate
100: thermoelectric conversion module
110: honeycomb molding die
120: insulating resin.
130: block
130′: block piece
140: cutter
150: P-type thermoelectric conversion material
151: P-type thermoelectric conversion element
160: N-type thermoelectric conversion material
161: N-type thermoelectric conversion element
300: thermoelectric conversion material
300P: P-type thermoelectric conversion material
300N: N-type thermoelectric conversion material
305: protrusion
310, 310P, and 310N: tube
320, 320P, and 320N: plated metal layer
350: thermoelectric conversion element
350P: P-type thermoelectric conversion element
350N: N-type thermoelectric conversion element
360: electric circuit board
365: circuit
400: cutter

1. A thermoelectric conversion element comprising:
an insulating tube; a thermoelectric conversion material with which the tube is filled; and a plated metal layer that is plated on one end or both ends of the thermoelectric conversion material, wherein:
the thermoelectric conversion material protrudes from an end surface of the tube, and the plated metal layer covers the protrusion of the thermoelectric conversion material.

2. The thermoelectric conversion element according to claim 1, wherein:
a height of the thermoelectric conversion material that protrudes from the end surface of the tube is within 5% of a height of the thermoelectric conversion element.

3. The thermoelectric conversion element according to claim 1, wherein:
the tube is a glass tube.

4. The thermoelectric conversion element according to claim 1, wherein:
both ends of the thermoelectric conversion material protrude from end surfaces of the tube, and the plated metal layer covers the protrusions of both ends of the thermoelectric conversion material.

5. The thermoelectric conversion element according to claim 1, wherein:
the plated metal layer covers a top surface and a side surface of the protrusion of the thermoelectric conversion material.

6. A thermoelectric conversion module comprising:
a P-type thermoelectric conversion element that includes an insulating tube, a P-type thermoelectric conversion material with which the tube is filled, and a plated metal layer that is plated on one end or both ends of the P-type thermoelectric conversion material;
an N-type thermoelectric conversion element that includes an insulating tube, an N-type thermoelectric conversion material with which the tube is filled, and a plated metal layer that is plated on one end or both ends of the N-type thermoelectric conversion material; and
an electric circuit board that is soldered to the P-type thermoelectric conversion element and the N-type thermoelectric conversion element through the plated metal layers, and that electrically connects the P-type thermoelectric conversion clement with the N-type thermoelectric conversion element in series, wherein:
the P-type thermoelectric conversion material and the N-type thermoelectric conversion material protrude from the end surface of tube respectively, and the plated metal layer covers the protrusion of the thermoelectric conversion material.
